(19) United States
(12) Patent Application Publication
(10) Pub. No.: US 2013/0138257 A1
(43) Pub. Date: May 30, 2013

(54) SYSTEM FOR OPERATING AN ELECTRIC POWER SYSTEM AND METHOD OF OPERATING THE SAME

(71) Applicant: Thomas Edenfeld, Osnabruck (DE)

(72) Inventor: Thomas Edenfeld, Osnabruck (DE)

(21) Appl. No.: 13/307,291

(22) Filed: Nov. 30, 2011

(51) Int. Cl. G06F 1/28; G06F 19/00; G01R 31/08

(52) U.S. Cl. 700/287; 702/59

(57) ABSTRACT

A protection and control system for an electric power system includes at least one electric power generation device and at least one voltage measurement device. The system also includes at least one memory device coupled to the voltage measurement device. The memory device is configured to store a plurality of voltage measurements of the electric power system. The system further includes at least one processor coupled in communication with the memory device. The processor is programmed to determine a change of voltage induced by an electric power generation device, and, determine an approximate location of an electrical fault as a function of the change of voltage induced by the electric power generation device.

### BACKGROUND OF THE INVENTION

The subject matter described herein relates generally to controlling operation of electric power systems, and more specifically, to controlling operation of a wind turbine farm in response to an electrical fault.

Generally, a wind turbine includes a rotor that includes a rotatable hub assembly having multiple blades. The blades transform wind energy into a mechanical rotational torque that drives one or more generators via the rotor. At least some of the known wind turbines are physically nested together in a common geographical region to form a wind turbine farm. Variable speed operation of the wind turbine facilitates enhanced capture of energy when compared to a constant speed operation of the wind turbine. However, variable speed operation of the wind turbine produces electric power having varying voltage and/or frequency. More specifically, the frequency of the electric power generated by the variable speed wind turbine is proportional to the speed of rotation of the rotor. A power converter may be coupled between the wind turbine's electric generator and an electric utility grid. The power converter receives the electric power from the wind turbine generator and transmits electricity having a fixed voltage and frequency for further transmission to the utility grid via a transformer. The transformer may be coupled to a plurality of power converters associated with the wind turbine farm.

The wind turbine may not be able to operate through certain grid events occurring downstream of the transformer, since wind turbine control devices require a finite period of time to sense the event, and then make adjustments to wind turbine operation to take effect after detecting such grid event. Therefore, in the interim period, the wind turbine may sustain wear and/or damage due to certain grid events. Such grid events include electrical faults that, under certain circumstances, may induce grid voltage fluctuations that may include low voltage transients with voltage fluctuations that approach zero volts. At least some known protective devices and systems facilitate continued operation during certain grid events. For example, for grid transients such as short circuits, a low, or zero voltage condition on the grid may occur. Under such conditions, such known protective devices and systems define a low and/or a zero voltage ride through (LVRT and ZVRT, respectively) capability. Such LVRT/ZVRT capabilities facilitate operation of the power converters of individual wind turbines and wind turbine farms to transmit reactive power into the utility grid. Such injection of reactive power into the grid facilitates stabilizing the grid voltage while grid isolation devices external to the wind farm, such as automated reclosers, will open and reclose to clear the fault while the LVRT/ZVRT features of the wind turbines maintain the generators coupled to the utility grid.

Such electrical faults may also occur upstream of the transformer, e.g., between the generator and the transformer, and/or within the generator. Most equipment configurations upstream of the utility grid transformer do not include automated open-reclosing devices that would clear such faults. Therefore, under such circumstances, it is possible that the LVRT/ZVRT features of the wind turbines may maintain the generators in service and that such reactive power transmission may reach the site of the short circuit and further feed an active electrical arc.

### BRIEF DESCRIPTION OF THE INVENTION

In one aspect, a protection and control system for an electric power system is provided. The electric power system includes at least one electric power generation device and at least one voltage measurement device. The system also includes at least one memory device coupled to the voltage measurement device. The memory device is configured to store a plurality of voltage measurements of the electric power system. The system further includes at least one processor coupled in communication with the memory device. The processor is programmed to determine a change of voltage induced by an electric power generation device, and, determine an approximate location of an electrical fault as a function of the change of voltage induced by the electric power generation device.

In another aspect, a method for controlling an electric power system during electrical fault conditions includes monitoring an electrical condition of the electric power system. The electric power system includes at least one electric power generating device and at least one controller. The method also includes increasing reactive power generation and transmission as a function of the monitored electrical condition. The method further includes monitoring a change in the value of the monitored electrical condition. The method also includes determining a location of the electrical fault condition as a function of the change in the monitored electrical condition.

In yet another aspect, an electric power system is provided. The electric power system includes at least one electric power generating device and at least one voltage measurement device. The system also includes at least one memory device coupled to the voltage measurement device. The memory device is configured to store a plurality of voltage measurements of the electric power system. The system further includes at least one processor coupled in communication with the memory device. The processor is programmed to determine a change of voltage induced by an electric power generation device, and, determine an approximate location of an electrical fault as a function of the change of voltage induced by the electric power generation device.

### BRIEF DESCRIPTION OF THE DRAWINGS

FIG. 1 is a block diagram of an exemplary computing device that may be used to monitor and/or control the operation of a portion of a wind turbine farm.

FIG. 2 is block diagram of a portion of an exemplary electric power system protection and control system.

FIG. 3 is a schematic view of an exemplary wind turbine.

FIG. 4 is a schematic view of the electric power system protection and control system shown in FIG. 2 that may be used with an exemplary wind turbine farm that includes the wind turbine shown in FIG. 3.

FIG. 5 is a schematic view of an exemplary electric power system that includes an exemplary electric power generation facility that includes the wind turbine farm shown in FIG. 4.

FIG. 6 is a tabular view of percentage voltage increases in response to particular case faults on the electric power system shown in FIG. 5.

FIG. 7 is a flowchart of an exemplary method of controlling the electric power system shown in FIG. 5 during electrical fault conditions.

### DETAILED DESCRIPTION OF THE INVENTION

As used herein, the term “blade” is intended to be representative of any device that provides reactive force when in motion relative to a surrounding fluid. As used herein, the term “wind turbine” is intended to be representative of any device that generates rotational energy from wind energy, and more specifically, converts kinetic energy of wind into mechanical energy. As used herein, the term “electric power generation device” is intended to be representative of any device that provides electric power derived from an energy resource. As used herein, the term “wind turbine generator” is intended to be representative of any wind turbine that includes an electric power generation device that generates electrical power from rotational energy generated from wind energy, and more specifically, converts mechanical energy converted from kinetic energy of wind to electrical power.

Technical effects of the methods, apparatus, systems, and computer-readable media described herein include at least one of: (a) monitoring reactive power transmitted to an electric power system to maintain a predetermined voltage thereon; (b) determining the approximate location of an electrical fault on an electric utility grid portion of the electric power system as a function of an increase in voltage generated by an electric power generation device; (c) determining the approximate location of an electrical fault within an electric power generation facility of the electric power system as a function of an increase in voltage generated by an electric power generation device; and (d) deactivating LVRT and/or ZVRT features of an electric power generation device to facilitate electric fault isolation within an electric power generation facility.

The methods, apparatus, systems, and computer readable media described herein facilitate identification of a location of an electrical fault on an electric utility grid portion or within an electric power generation facility of an electric power system as a function of an increase in voltage generated by an electric power generation device. Also, the methods, apparatus, systems, and computer readable media described herein facilitate deactivating LVRT and/or ZVRT features of an electric power generation device to decrease the effects of an electrical fault within the electric power generation facility. Although generally described herein with respect to a wind turbine farm, the methods and systems described herein are applicable to any type of electric generation system including, for example, solar power generation systems, fuel cells, geothermal generators, hydropower generators, and/or other devices that generate power from renewable and/or non-renewable energy sources.

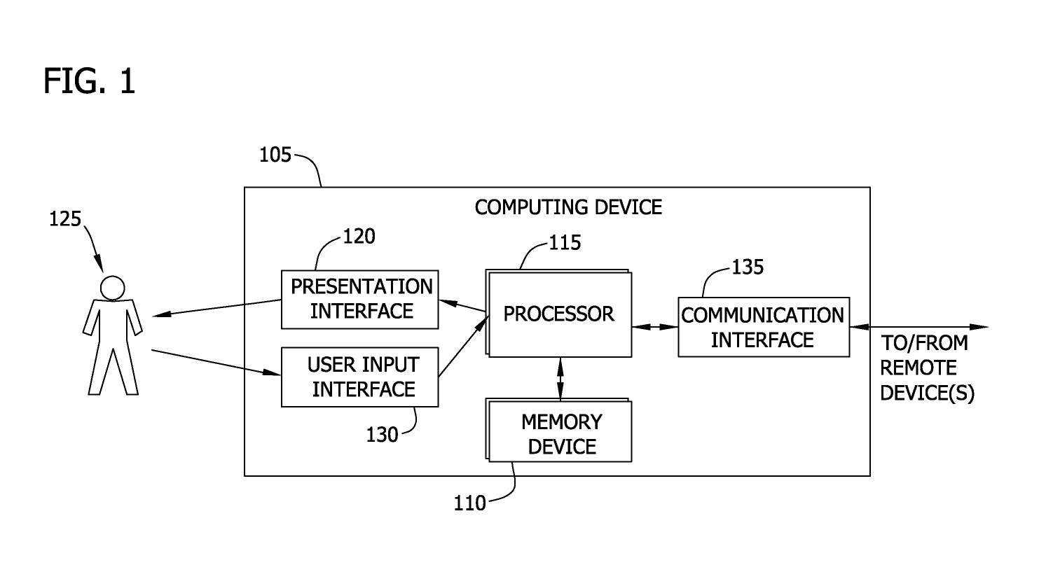

FIG. 1 is a block diagram of an exemplary computing device 105 that may be used to monitor and/or control the operation of a portion of a wind turbine farm (not shown in FIG. 1). Computing device 105 includes a memory device 110 and a processor 115 operatively coupled to memory device 110 for executing instructions. Processor 115 may include one or more processing units (e.g., in a multi-core configuration). In some embodiments, executable instructions are stored in memory device 110. Computing device 105 is configurable to perform one or more operations described herein by programming processor 115. For example, processor 115 may be programmed by encoding an operation as one or more executable instructions and providing the executable instructions in memory device 110. In the exemplary embodiment, memory device 110 is one or more devices that enable storage and retrieval of information such as executable instructions and/or other data. Memory device 110 may include one or more computer readable media, such as, without limitation, random access memory (RAM), dynamic random access memory (DRAM), static random access memory (SRAM), a solid state disk, a hard disk, read-only memory (ROM), erasable programmable ROM (EPROM), electrically erasable programmable ROM (EEPROM), and/or non-volatile RAM (NVRAM) memory. The above memory types are exemplary only, and are thus not limiting as to the types of memory usable for storage of a computer program.

Further, as used herein, the terms “software” and “firmware” are interchangeable, and include any computer program stored in memory for execution by personal computers, workstations, clients and servers.

Memory device 110 may be configured to store operational measurements including, without limitation, utility electric power grid (not shown in FIG. 1) voltage and current readings, substation (not shown in FIG. 1) voltage and current readings, localized voltage and current readings throughout an electric power generation system (not shown in FIG. 1), and/or any other type of data. In some embodiments, processor 115 removes or “purges” data from memory device 110 based on the age of the data. For example, processor 115 may overwrite previously recorded and stored data associated with a subsequent time and/or event. In addition, or alternatively, processor 115 may remove data that exceeds a predetermined time interval. Also, memory device 110 includes, without limitation, sufficient data, algorithms, and commands to facilitate centralized protection and control of electric power systems (discussed further below).

In some embodiments, computing device 105 includes a presentation interface 120 coupled to processor 115. Presentation interface 120 presents information, such as a user interface and/or an alarm, to a user 125. In one embodiment, presentation interface 120 includes a display adapter (not shown) that is coupled to a display device (not shown), such as a cathode ray tube (CRT), a liquid crystal display (LCD), an organic LED (OLED) display, and/or an “electronic ink” display. In some embodiments, presentation interface 120 includes one or more display devices. In addition, or alternatively, presentation interface 120 includes an audio output device (not shown) (e.g., an audio adapter and/or a speaker) and/or a printer (not shown). In some embodiments, presentation interface 120 presents an alarm associated with a synchronous machine (not shown in FIG. 1), such as by using a human machine interface (HMI) (not shown).

In some embodiments, computing device 105 includes a user input interface 130. In the exemplary embodiment, user input interface 130 is coupled to processor 115 and receives input from user 125. User input interface 130 may include, for example, a keyboard, a pointing device, a mouse, a stylus, a touch sensitive panel (e.g., a touch pad or a touch screen), a gyroscope, an accelerometer, a position detector, and/or an audio input interface (e.g., including a microphone). A single component, such as a touch screen, may function as both a display device of presentation interface 120 and user input interface 130.

A communication interface 135 is coupled to processor 115 and is configured to be coupled in communication with one or more other devices, such as a sensor or another computing device 105, and to perform input and output operations with respect to such devices. For example, communication interface 135 may include, without limitation, a wired network adapter, a wireless network adapter, a mobile telecommunications adapter, a serial communication adapter, and/or a parallel communication adapter. Communication interface 135 may receive data from and/or transmit data to one or more remote devices. For example, a communication interface 135 of one computing device 105 may transmit an alarm to the communication interface 135 of another computing device 105.

Presentation interface 120 and/or communication interface 135 are both capable of providing information suitable for use with the methods described herein (e.g., to user 125 or another device). Accordingly, presentation interface 120 and communication interface 135 may be referred to as output devices. Similarly, user input interface 130 and communication interface 135 are capable of receiving information suitable for use with the methods described herein and may be referred to as input devices.

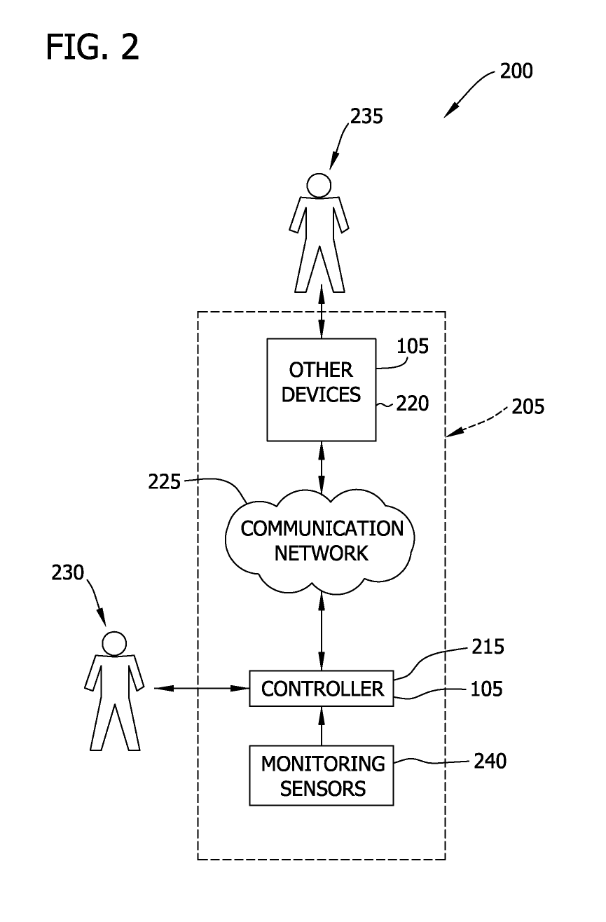

FIG. 2 is block diagram of a portion of an exemplary electric power system protection and control system 200 that may be used to monitor and/or operate at least a portion of an electric power system 205. Protection and control system 200 includes a protection and control system controller 215 that may be coupled to other devices 220 via a communication network 225. Protection and control system controller 215 may be, without limitation, a substation-level centralized controller, a wind turbine-level centralized controller, and one of a plurality of distributed controllers. Embodiments of network 225 may include operative coupling with, without limitation, the Internet, a local area network (LAN), a wide area network (WAN), a wireless LAN (WLAN), and/or a virtual private network (VPN). While certain operations are described below with respect to particular computing devices 105, it is contemplated that any computing device 105 may perform one or more of the described operations. For example, controller 215 may perform all of the operations below.

Referring to FIGS. 1 and 2, controller 215 is a computing device 105. In the exemplary embodiment, computing device 105 is coupled to network 225 via communication interface 135. In an alternative embodiment, controller 215 is integrated with other devices 220. As used herein, the term “computer” and related terms, e.g., “computing device”, are not limited to integrated circuits referred to in the art as a computer, but broadly refers to a microcontroller, a microcomputer, a programmable logic controller (PLC), an application specific integrated circuit, and other programmable circuits (none shown in FIG. 2), and these terms are used interchangeably herein.

Controller 215 interacts with a first operator 230 (e.g., via user input interface 130 and/or presentation interface 120). In one embodiment, controller 215 presents information about electric power system 205, such as alarms, to operator 230. Other devices 220 interact with a second operator 235 (e.g., via user input interface 130 and/or presentation interface 120). For example, other devices 220 present alarms and/or other operational information to second operator 235. As used herein, the term “operator” includes any person in any capacity associated with operating and maintaining electric power system 205, including, without limitation, shift operations personnel, maintenance technicians, and system supervisors.

In the exemplary embodiment, protection and control system 200 includes one or more monitoring sensors 240. Monitoring sensors 240 collect operational measurements including, without limitation, voltage and current readings throughout electric power system 205, including, without limitation, substation and wind turbine generator readings, and/or any other type of data. Monitoring sensors 240 repeatedly (e.g., periodically, continuously, and/or upon request) transmit operational measurement readings at the time of measurement. For example, monitoring sensors 240 may generate and transmit an electrical current between a minimum value (e.g., 4 milliamps (mA)) and a maximum value (e.g., 20 mA). The minimum sensor current value of 4 mA indicates that the lowest expected value for a measured condition is detected. The maximum current value indicates that the highest expected value for a measured condition is detected. Controller 215 receives and processes the operational measurement readings. Also, controller 215 includes, without limitation, sufficient data, algorithms, and commands to facilitate centralized and/or distributed protection and control of electric power system 205 (discussed further below).

Also, in the exemplary embodiment, electric power system 205 includes additional monitoring sensors (not shown) similar to monitoring sensors 240 that collect operational data measurements associated with the remainder of electric power system 205 including, without limitation, data from additional feeders and environmental data, including, without limitation, local outside temperatures. Such data is transmitted across network 225 and may be accessed by any device capable of accessing network 225 including, without limitation, desktop computers, laptop computers, and personal digital assistants (PDAs) (neither shown).

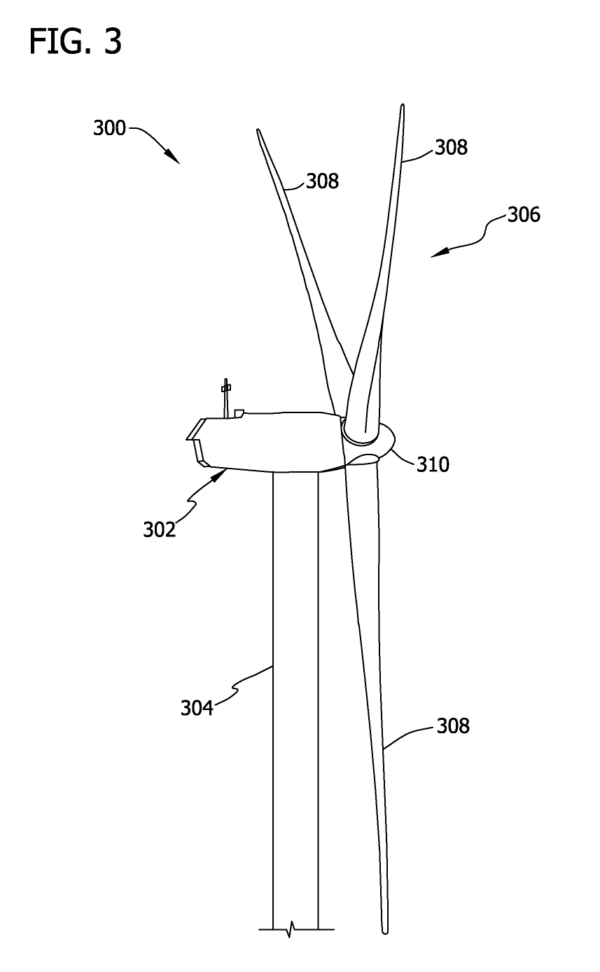

FIG. 3 is a schematic view of an exemplary wind turbine generator 300. Wind turbine generator 300 is an electric power generation device including a nacelle 302 housing a generator (not shown in FIG. 3). Nacelle 302 is mounted on a tower 304 (a portion of tower 304 being shown in FIG. 3). Tower 304 may be any height that facilitates operation of wind turbine generator 300 as described herein. Wind turbine generator 300 also includes a rotor 306 that includes three rotor blades 308 attached to a rotating hub 310. Alternatively, wind turbine generator 300 includes any number of blades 308 that facilitates operation of wind turbine generator 300 as described herein. In the exemplary embodiment, wind turbine generator 300 includes a gearbox (not shown in FIG. 3) rotatably coupled to rotor 306 and a generator (not shown in FIG. 3).

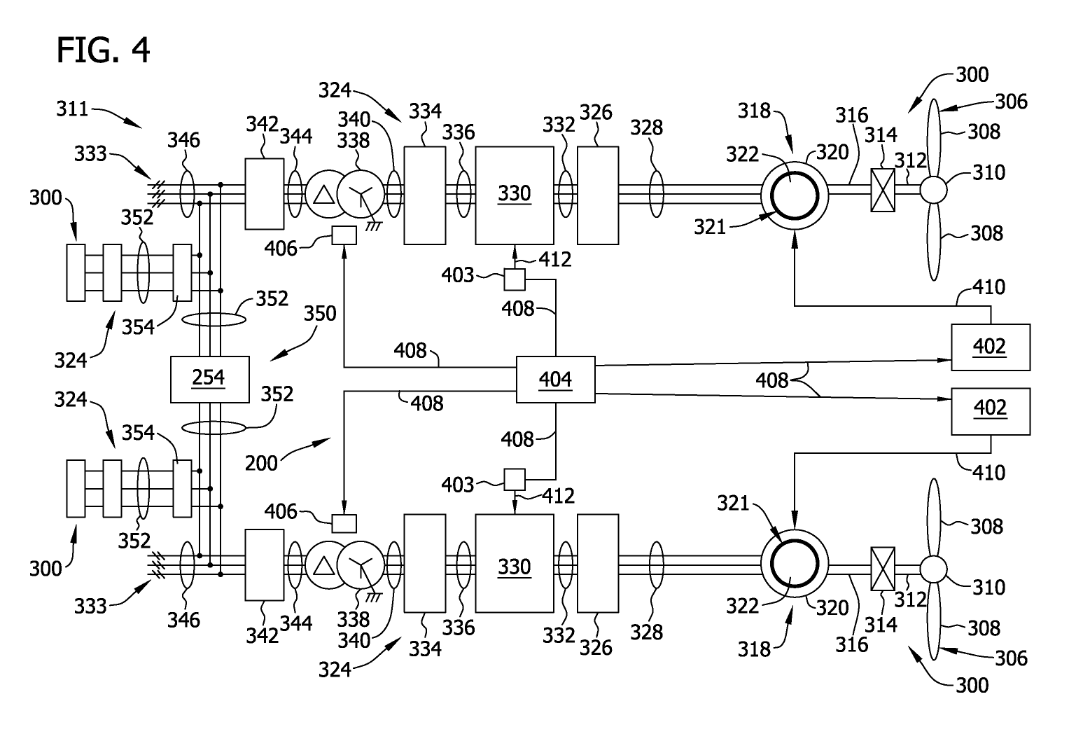

FIG. 4 is a schematic view of exemplary wind turbine farm electrical control and protection system 200 that may be used with wind turbine generator 300. In the exemplary embodiment, each wind turbine generator 300 is positioned within a wind turbine farm 311 that is at least partially defined geographically and/or electrically, i.e., farm 311 may be defined by a number of wind turbine generators 300 in a particular geographic area, or alternatively, defined by each wind turbine generator's 300 electrical connectivity to a common substation. In the exemplary embodiment, each wind turbine generator 300 that defines wind turbine farm 311 is substantially identical to each other wind turbine generator 300. Alternatively, any combination of any type of wind turbine generator is used that enables operation of wind turbine farm 311 as described herein.

In the exemplary embodiment, rotor 306 includes a plurality of rotor blades 308 coupled to rotating hub 310. Rotor 306 also includes a low-speed shaft 312 rotatably coupled to hub 310. Low-speed shaft 312 is coupled to a step-up gearbox 314 that is configured to step up the rotational speed of low-speed shaft 312 and transfer that speed to a high-speed shaft 316. In the exemplary embodiment, gearbox 314 has a step-up ratio of approximately 70:1. For example, low-speed shaft 312 rotating at approximately 20 revolutions per minute (rpm) coupled to gearbox 314 with an approximately 70:1 step-up ratio generates a high-speed shaft 316 speed of approximately 1400 rpm. Alternatively, gearbox 314 has any step-up ratio that facilitates operation of wind turbine generator 300 as described herein. Wind turbine generator 300 may also include a direct-drive generator having a generator rotor (not shown in FIG. 3) that is rotatably coupled to rotor 306 without any intervening gearbox.

High-speed shaft 316 is rotatably coupled to a generator 318. In the exemplary embodiment, generator 318 is a synchronous permanent magnet generator (PMG) that includes a rotor 322 configured with a plurality of permanent magnets (not shown) and a stator 320 extending about rotor 322. Stator 320 and rotor 322 define a generator air gap 321 therebetween. In the exemplary embodiment, a torque induced within generator air gap 321 opposes the torque applied by rotor 306. A balance between the wind-induced torque on rotor 306 and air gap torque induced on generator 318 facilitates stable operation of wind turbine generator 300. Generator stator 320 is magnetically coupled to generator rotor 322. Alternatively, generator 318 is an electrically excited synchronous generator (EESG) that includes a rotor configured with a plurality of excitation windings (not shown) and a stator. In alternative embodiments, any generator that enables operation of wind turbine generator 300 as described herein is used.

In the exemplary embodiment, each wind turbine generator 300 is electrically coupled to an electric power train 324. Electric power train 324 includes a stator synchronizing switch 326. Generator stator 320 is electrically coupled to stator synchronizing switch 326 via a stator bus 328. Stator bus 328 transmits three-phase power from stator 320 to switch 326. In the exemplary embodiment, electric power train 324 includes a full power conversion assembly, or converter 330, wherein converter 330 is an electric power generating device. Synchronizing switch 326 is electrically coupled to converter 330 via a conversion bus 332 that transmits three-phase power from stator 320 to assembly 330. Converter 330 facilitates channeling electric power between stator 320 and an electric power transmission and distribution grid 333. Stator synchronizing switch 326 is electrically coupled to a main transformer circuit breaker 334 via a system bus 336.

In some alternative embodiments of wind turbines (not shown), doubly-fed induction generators (DFIGs) (not shown) are used, as contrasted to synchronous permanent magnet generator 318. Such configurations include DFIG converters that include two three-phase AC-DC converters coupled by a DC link. One AC-DC converter is connected to the grid and stator of the generator, and the other AC-DC converter is connected to the rotor of the generator. If the generator rotor is being turned at a speed slower than the synchronous speed, the DFIG converter will excite the rotor with reactive power. The rotor will then appear to be turning at a synchronous speed with respect to the stator and the stator will make the desired (synchronous frequency) power. If the generator rotor is being turned at synchronous speed, the DFIG converter will excite the rotor with DC power and the stator will generate the desired (synchronous frequency) power. If the generator rotor is being turned at a speed faster than the synchronous speed, the DFIG converter will excite the rotor with reactive power while at the same time extracting real power from the rotor. The rotor will then appear to be turning at a synchronous speed with respect to the stator and the stator will generate the desired (synchronous frequency) power. The frequency of the power extracted from the rotor will be converted to the synchronous frequency and added to the power generated by the stator.

Electric power train 324 further includes a turbine transformer 338. System circuit breaker 334 is electrically coupled to turbine transformer 338 via a generator-side bus 340. Turbine transformer 338 is electrically coupled to a grid circuit breaker 342 via a breaker-side bus 344. Grid breaker 342 is connected to electric power transmission and distribution grid 333 via a grid bus 346.

In the exemplary embodiment, a plurality of electric power trains 324 are electrically coupled to grid 333 via a wind turbine farm substation and/or substation 350. Substation 350 includes a plurality of substation buses 352 and at least one substation circuit breaker 354 to facilitate both electrical interconnection and electrical isolation of associated wind turbine generators 300 and electric power trains 324.

During operation, wind impacts blades 308 and blades 308 transform wind energy into a mechanical rotational torque that rotatingly drives low-speed shaft 312 via hub 310. Low-speed shaft 312 drives gearbox 314 that subsequently steps up the low rotational speed of shaft 312 to drive high-speed shaft 316 at an increased rotational speed. High speed shaft 316 rotatingly drives rotor 322 of generator 318. A rotating magnetic field is induced by rotor 322 and a voltage is induced within stator 320 that is magnetically coupled to rotor 322 via generator air gap 321. Generator 318 converts the rotational mechanical energy to a sinusoidal, three-phase alternating current (AC) electrical energy signal in stator 320.

Torque is induced in generator 318 within air gap 321 between rotor 322 and stator 320 that opposes the torque applied by rotor high speed shaft 316. A balance between the wind-induced torque on rotor 322 and air gap torque induced on generator 318 facilitates stable operation of wind turbine generator 300. Operational adjustments to wind turbine generator 300, for example, pitch adjustments of blades 308, may cause an imbalance between the rotor torque and the air gap torque. Also, events on grid 333, for example, low voltages or zero voltages on grid 333, may cause an imbalance between the rotor torque and the air gap torque. Converter 330 controls the air gap torque which facilitates controlling the power output of generator 318.

Further, during operation, electrical power generated within stator 320 is transmitted to converter 330. In the exemplary embodiment, electrical, three-phase, sinusoidal, AC power is generated within stator 320 and is transmitted to converter 330 via bus 328, switch 326 and bus 332. Within converter 330, the electrical power is rectified from sinusoidal, three-phase AC power to direct current (DC) power. The DC power is transmitted to an inverter (not shown) that converts the DC electrical power to three-phase, sinusoidal AC electrical power with pre-determined voltages, currents, and frequencies. Converter 330 compensates or adjusts the frequency of the three-phase power from stator 320 for changes, for example, in the wind speed at hub 310 and blades 308. Therefore, in this manner, mechanical and electrical rotor frequencies are decoupled from grid frequency.

Moreover, in operation, the converted AC power is transmitted from converter 330 to turbine transformer 338 via bus 336, breaker 334 and bus 340. Turbine transformer 338 steps up the voltage amplitude of the electrical power and transformed electrical power is further transmitted to substation 350 and grid 333 via bus 344, circuit breaker 342, bus 346 and/or buses 352 and circuit breakers 354.

In the exemplary embodiment, electric power system protection and control system 200 includes a plurality of turbine controllers 402. Each turbine controller 402 is substantially similar to controller 215 (shown in FIG. 2) and includes at least one processor 115, memory device 110, and at least one processor input and/or channel, e.g., communications interface 135 (all shown in FIG. 1).

Processors 115 for each turbine controller 402 process information transmitted from a plurality of electrical and electronic devices that may include, without limitation, voltage and current transducers (not shown). Memory device 110 stores and transfers information and instructions to be executed by processor 115. Memory devices 110 can also be used to store and provide temporary variables, static (i.e., non-changing) information and instructions, or other intermediate information to processors 115 during execution of instructions by processors 115. Instructions that are executed include, without limitation, resident conversion and/or comparator algorithms and operational commands. The execution of sequences of instructions is not limited to any specific combination of hardware circuitry and software instructions.

In the exemplary embodiment, each turbine controller 402 is configured to receive a plurality of voltage and electric current measurement signals (not shown) from voltage and electric current sensors (not shown). Such sensors may be coupled to any portion of electric power train 324, such as at least one of each of the three phases of bus 346 and/or system bus 336. Alternatively, voltage and electric current sensors are electrically coupled to any portion of electric power train 324 and/or substation 350 and/or grid 333 that facilitates operation of electric power system protection and control system 200 as described herein. Alternatively, controller 402 is configured to receive any number of voltage and electric current measurement signals from any number of voltage and electric current sensors.

Moreover, in the exemplary embodiment, each turbine controller 402 includes sufficient programming, including algorithms, to monitor and control at least some of the operational variables associated with wind turbine generator 300 including, without limitation, at least one of generator field strength, shaft speeds, excitation voltage and current, total electric production of generator 318, bearing temperatures, and/or blade pitch.

Also, in the exemplary embodiment, electric power system protection and control system 200 includes a plurality of converter controllers 403. Each converter controller 403 is substantially similar to controller 215 and turbine controller 402 and includes at least one processor 115, memory device 110, and at least one processor input and/or channel, e.g., communications interface 135.

Each converter controller 403 is configured to receive a plurality of voltage and electric current measurement signals (not shown) from voltage and electric current sensors (not shown) associated with full power conversion assembly 330, thereby facilitating control of converters 330. Alternatively, turbine controllers 402 are coupled in communication with converters 330 to facilitate control of converters 330. Each controller 403 includes sufficient programming, including algorithms, to monitor and control at least some of the operational variables associated with converters 330 including, without limitation, firing rate of firing devices (not shown), alternating current and direct current voltage amplitudes, reactive power transmission, and the power factor of the electric power transmitted therefrom to turbine transformer 338. In those alternative embodiments that include DFIGs, converter controllers 403 may be configured to operate as DFIG controllers as described above.

In the exemplary embodiment, electric power system protection and control system 200 includes a wind turbine farm controller 404 that is operatively coupled to each turbine controller 402 and converter controller 403. Controller 404 is physically similar to turbine controllers 402, converter controllers 403, and controller 215 and functionally similar to controllers 402 and 403 with the exception that each turbine controller 402 only controls the associated wind turbine generator 300 and each converter controller 403 only controls the associated converter 330. In contrast, wind turbine farm controller 404 controls more than one wind turbine generator 300 and more than one converter 330.

Also, in contrast to turbine controller 402 and converter controller 403, wind turbine farm controller 404 is coupled to a turbine transformer tap changer 406. In the exemplary embodiment, turbine transformer tap changer 406 is a motorized, controllable, on-load tap changer (OLTC) coupled to turbine transformer 338. Wind turbine farm controller 404 includes sufficient programming, including algorithms, to operate tap changer 406 to monitor and change a secondary voltage, transmission of reactive power, and/or power factor on breaker-side bus 344. Each tap setting within turbine transformer 338 is determined based on predetermined voltage settings.

Further, in the exemplary embodiment, electric power system protection and control system 200 is configured to operate as a distributed control system and/or a centralized control system. As a distributed control system, controllers 402, 403, and 404 monitor and control only the associated wind turbine generator 300, the associated converter 330, and the associated tap changer 406, respectively. Alternatively, as a centralized control system, distributed controllers 402 and 403 respond to commands from a centralized controller, e.g., controller 404. Also, alternatively, all controllers 402, 403, and 404 respond to a master controller (not shown). In a further alternative embodiment, any configuration of the controllers within wind farm 311 that enables operation of wind farm 311 as described herein is used.

Also, in the exemplary embodiment, wind turbine park controller 404 is coupled in communication with turbine controllers 402, converter controllers 403, and tap changers 406 via a plurality of communications channels 408. Turbine controllers 402 are coupled in communication with wind turbine generates 300 via a plurality of communications channels 410. Converter controllers 403 are coupled in communication with converters 330 via a plurality of communications channels 412. Communications channels 408, 410, and 412 are any combination of communication devices that enable operation of wind turbine generators 300 and electric power system protection and control system 200, as described herein, including, without limitation, wireless communications networks, fiber optic networks, and cable/wire communications networks.

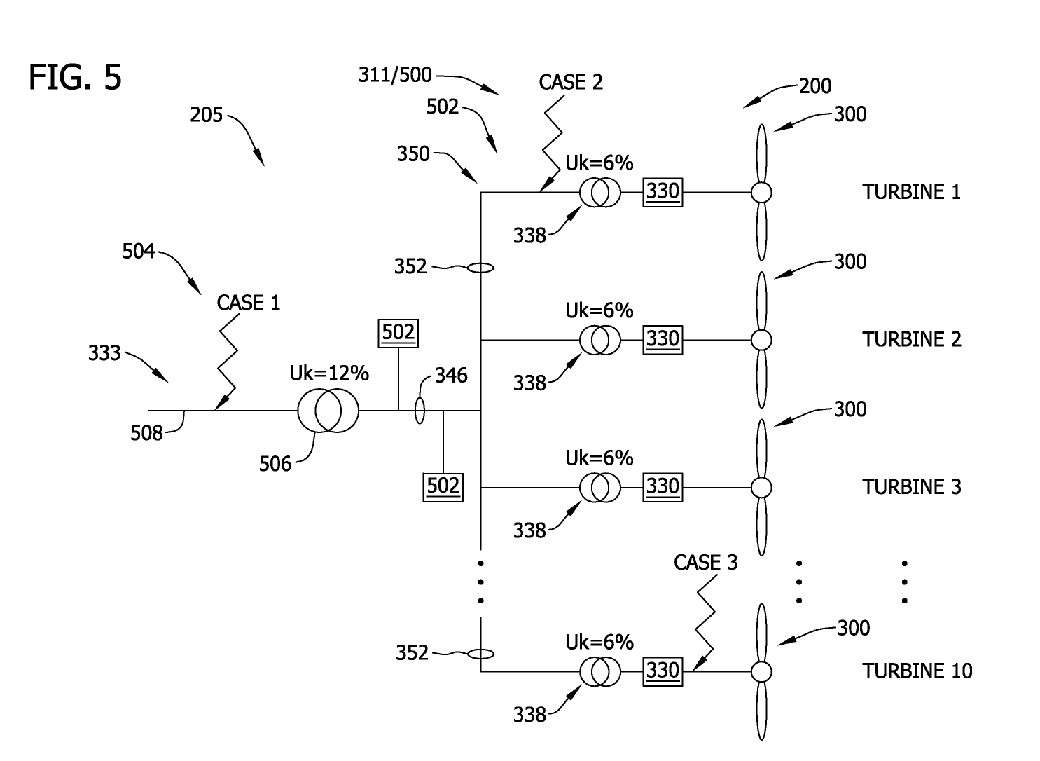

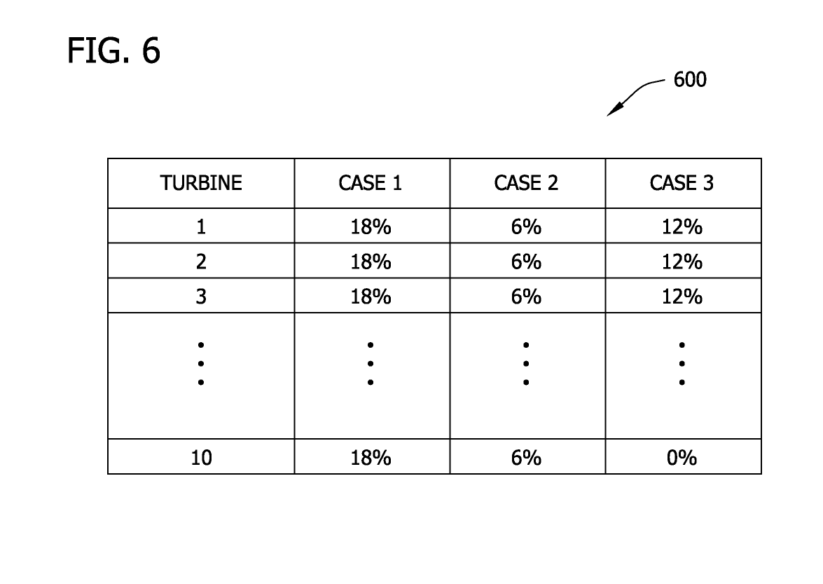

FIG. 5 is a schematic view of electric power system 205 that includes an electric power generation facility 500 including wind turbine farm 311. FIG. 6 is a tabular view, i.e., table 600 of percentage voltage increases in response to particular case faults on electric power system 205 (shown in FIG. 5). FIG. 5 will be referred to individually below, and in conjunction with FIG. 6 to compare and/or contrast the associated case faults.

Referring to FIG. 5, in the exemplary embodiment, wind turbine farm 311 is electric power generation facility 500 of electric power system 205. Alternatively, additional electric power generation apparatus are included within electric power generation facility 500. Electric power generation facility 500 includes a plurality of wind turbine strings 502. Each wind turbine string 502 includes ten wind turbine generators 300. FIG. 5 illustrates a first wind turbine generator 300, a second wind turbine generator 300, a third wind turbine generator 300, and a tenth wind turbine generator 300 that are labeled as turbine 1, turbine 2, turbine 3, and turbine 10, respectively. Alternatively, electric power generation facility 500 includes any number of strings 502, and strings 502 include any number of wind turbine generators 300 that enable operation of electric power generation facility 500 as described herein. In the exemplary embodiment, each wind turbine generator 300 and associated converters 330 and turbine transformers 338 are rated to generate and transmit approximately 40 amperes AC to substation bus 352.

Also, in the exemplary embodiment, electric power system 205 includes an electric utility grid portion 504 that includes electric power transmission and distribution grid 333 and a main electric power transformer 506 coupled to grid bus 346. Grid 333 includes a plurality of distribution feeders 508 (only one shown) coupled to transformer 506. In operation, when all ten wind turbine generators 300 of string 502 are in service, approximately 400 amperes AC are transmitted through grid bus 346. Electric current transmitted by additional strings 502 are additive.

In some alternative embodiments of electric power generation facility 500, a combination of electric power generation devices are used. In at least one alternative embodiment, at least some wind turbine generators 300 are replaced with solar panels (not shown) coupled to form one or more solar arrays (not shown) to facilitate operating wind turbine farm 311 at a desired power output with supplemental, solar-generated power. Also, alternatively, electric power generation facility 500 is an exclusively solar power generation facility coupled to substation 350 to generate and transmit electric power to grid 333. In such configurations, each solar power generation unit may be an individual solar panel or an array of solar panels. In one embodiment, such solar power generation system includes a plurality of solar panels and/or solar arrays coupled together in a series-parallel configuration to facilitate generating a desired current and/or voltage output from the solar power generation system. Solar panels include, in one alternative embodiment, one or more of a photovoltaic panel, a solar thermal collector, or any other device that converts solar energy to electrical energy. In such alternative embodiments, each solar panel is a photovoltaic panel that generates a substantially direct current power as a result of solar energy striking solar panels.

Also, in such alternative embodiments, each solar array is coupled to a power converter that is similar to at least a portion of power converter 330 that converts the DC power to AC power that is transmitted to a transformer similar to transformer 338 and then to substation 350. Furthermore, although generally described herein with respect to wind turbine farm 311 and a solar array facility, the methods and systems described herein are applicable to any type of electric generation system including, for example, fuel cells, geothermal generators, hydropower generators, and/or other devices that generate power from renewable and/or non-renewable energy sources.

In the exemplary embodiment, electric power system protection and control system 200 determines an approximate location of a grid contingency event that includes, without limitations, electrical faults such as short circuits associated with downed cables/wires. Electric conduits, such as distribution system cabling, have an impedance value per unit length of the conduit. Therefore, larger lengths of cable, and longer distances between a fault and a measuring device, have larger impedance values than shorter lengths and distances. Grid contingency events typically draw increased current through grid distribution feeders 508 and induce decreased voltages along feeders 508.

Also, in the exemplary embodiment, electric power system protection and control system 200 is configured to identify the occurrence of a grid contingency event. Further, electric power system protection and control system 200 facilitates continued operation of electric power generation facility 500 during certain grid contingency events. Moreover, system 200 compensates for the voltage decrease on grid 333, e.g., converter controller 403 (shown in FIG. 4) provides converter 330 with command signals to increase a reactive current output of associated converter 330 during recovery from a grid contingency event to facilitate maintaining a substantially constant grid voltage and facilitate prevention of voltage collapse.

System 200 facilitates an injection of reactive power into grid 333 by coordinating operation of converters 330, wind turbines 300, and tap changers 406 (shown in FIG. 4). Such coordinated operation is enabled through turbine controllers 402, converter controllers 403, DFIG converters (not shown), and/or wind turbine park controllers 404 via communication channels 408, 410, and 412. Also, such coordinated operation includes, without limitation, a substantially equalized distribution of reactive power injection from all of available converters 330 within each of turbine strings 502. Alternatively, such coordinated operation includes, without limitation, a substantially levelized distribution of reactive power injection from all of converters 330 within each of turbine strings 502 as a function of the present loadings and ratings of each of converters 330. Moreover, such coordinated operation facilitates a rapid response to the grid contingency event with less structural and electrical stresses on each device, in contrast to utilizing only a few devices to inject reactive power into grid 333.

For example, for grid transients such as short circuits, a low, or zero voltage condition on grid 333 may occur. Under such conditions, protection and control system 200 define a low and/or a zero voltage ride through (LVRT and ZVRT, respectively) capability. Such LVRT/ZVRT capabilities facilitate operation of converters 330 of individual turbines 1 through 10 and wind turbine farm 311 to continue to transmit reactive power into grid 333. Such injection of reactive power into grid 333 facilitates stabilizing the grid voltage while grid isolation devices (not shown) not directly associated with electric power generation facility 500, such as automated reclosers, open and reclose to clear the fault while the LVRT/ZVRT features of protection and control system 200 maintain turbines 1 through 10 coupled to grid 333.

There is a known relationship between electric current, voltage, and impedance. Therefore, a distance to the fault associated with the grid contingency event may be approximated as a function of the increase in voltage induced by the injection of reactive power into the grid by converters 330.

Electrical faults may also occur upstream of transformer 506, e.g., on substation 350, downstream of turbine transformer 338. Typically, opening of circuit breakers within substation 350 will isolate the fault. During such fault isolation, the LVRT/ZVRT features of protection and control system 200 facilitate maintaining turbines 1 through 10 coupled to grid 333. Such coupling to grid 333 is facilitated by increasing the injection of reactive current into grid 333 from converters 330 through substation bus 352 to support the voltage within electric power generation facility 500. Moreover, as discussed further below, electrical faults may also occur upstream of turbine transformer 338, e.g., within generator 318 (shown in FIG. 4) of a wind turbine generator 300, and use of the LVRT/ZVRT features of protection and control system 200 may inhibit isolation of the fault, thereby increasing a potential for further arc damage.

In the exemplary embodiment, protection and control system 200 includes sufficient programming, including algorithms, to determine an approximate distance to a fault as a function of a percentage voltage increase as generated by converters 330. Also, protection and control system 200 includes sufficient programming, including algorithms and instructions, to prevent selected LVRT/ZVRT features in selected turbines from operating, thereby facilitating more expedient tripping of the affected turbine and facilitating fault isolation.

FIGS. 5 and 6 show three cases for the exemplary embodiment, wherein all three cases are described further below. Case 1, as shown in FIG. 5, includes a grid contingency event, e.g., an electrical fault in the form of a short circuit caused by a falling tree branch on a cable of distribution feeder 508. Voltage on distribution feeder 508 decreases substantially instantaneously, thereby drawing down the voltage throughout the portion of grid 333 coupled to main transformer 506. Protection and control system 200 receives voltage measurements from grid 333 and system 200 includes sufficient programming to identify the occurrence of such grid contingency event. However, the location of such fault requires further determination by system 200.

Moreover, in the exemplary embodiment, system 200 is programmed with sufficient data defining a voltage threshold curve that is a function of a value of the magnitude and/or percentage of the voltage increase, the time elapsed during the voltage increase, and the impedance of the electric cabling per unit distance. The voltage on grid 333 increases as reactive current is injected into grid 333 by converters 330. The measured increase in voltage by converters 330 to support grid voltage is a function of the total impedance between the fault and converters 330. Therefore, as the distance of the fault from converters 330 increases, the impedance increases, and the associated increase in voltage from converters 330 increases. In contrast, as the distance of the fault from converters 330 decreases, the impedance decreases, and the associated increase in voltage from converters 330 decreases. Therefore, system 200 includes a predetermined relationship between distance to a fault and a percentage increase in the voltage induced by converters 330.

System 200 also includes sufficient programming to enable LVRT/ZVRT features therein to facilitate continued operation of electric power generation facility 500 during such voltage transients induced by such grid contingency events as described for case 1. System 200 compensates for the voltage decrease on grid 333, wherein each converter controller 403 and/or park controller 404 commands an increase of reactive current output of associated converters 330 concurrently with grid-related electrical isolation of the site of the grid contingency event. Such isolation activities include operation of grid isolation devices, such as automated reclosers, opening and reclosing to clear the fault. Such compensation includes the LVRT/ZVRT features of system 200 to command converters 330 of individual turbines 1 through 10 and electric power generation facility 500 to continue to transmit reactive current into grid 333 to facilitate stabilizing the grid voltage, thereby facilitating restoring and maintaining a substantially constant voltage on grid 333. Moreover, as the reactive power transmission from converters 330 increases, the active power component of the apparent power transmission value decreases, thereby facilitating a decrease of the magnitude of active current transmitted to the fault, and maintaining the apparent power output of converters 330 within predetermined parameters.

As described above, FIG. 6 is a tabular view, i.e., table 600 of percentage voltage increases in response to particular case faults on electric power system 205 (shown in FIG. 5). Referring to FIGS. 5 and 6, for case 1 as described above, the voltage threshold determined to approximate the position of electrical faults a predetermined distance outside of substation 350 is established to be approximately 18%. Alternatively, any threshold value that is determined to position a fault on grid 333 external to electric power generation facility 500 is used. As shown in FIG. 6, each converter 330 associated each of turbines 1 through 10 indicates a substantially uniform 18% voltage increase. Therefore, since system 200 has determined that the fault is external to substation 350 on grid 333, the LVRT/ZVRT features of system 200 continue to command converters 330 to support grid voltage. As described above, for a predetermined impedance per unit length of distribution conduit, an approximation is made of ranges along feeder 508 where the fault may be located as a function of the measured voltage increase by converters 330.

Referring again solely to FIG. 5, in the exemplary embodiment, a second case is shown and described. Case 2 includes an electrical fault in the form of a short circuit on substation bus 352 downstream of transformer 338 associated with turbine 1. Voltage on substation bus 352 decreases substantially instantaneously, thereby drawing down the voltage throughout wind turbine string 502. Protection and control system 200 receives voltage measurements from substation bus 352 and system 200 includes sufficient programming to identify the occurrence of such fault. However, the location of such fault requires further determination by system 200.

As described above, in the exemplary embodiment, system 200 is programmed with sufficient data thereby defining a voltage threshold curve that is a function of a value of the magnitude and/or percentage of the voltage increase, the time elapsed during the voltage increase, and the impedance of the electric cabling per unit distance. System 200 also includes sufficient programming to enable LVRT/ZVRT features therein to initially facilitate continued operation of a substantial portion of electric power generation facility 500 during such voltage transients induced by such substation events.

System 200 initially compensates for the voltage decrease on substation 350 due to the fault associated with case 2, wherein each converter controller 403 and/or park controller 404 commands an increase of reactive current output of associated converters 330 concurrently with electrical isolation activities of the site of the fault. Such isolation activities include operation of substation isolation devices, e.g., automated opening of the nearest substation circuit breaker 354 to clear the fault. Typically, such isolation occurs after approximately three cycles, i.e., approximately 50 milliseconds (ms).

Such compensation includes the LVRT/ZVRT features of system 200 to command converters 330 of each of turbines 1 through 10 and electric power generation facility 500 to initially transmit reactive current into substation bus 352 to facilitate stabilizing the substation voltage, thereby facilitating restoring and maintaining a substantially constant voltage on substation 350. Moreover, as the reactive power transmission from converters 330 increases, the active power component of the apparent power transmission value decreases, thereby facilitating a decrease of the magnitude of active current transmitted to the fault, and maintaining the apparent power output of converters 330 within predetermined parameters. Typically, it takes approximately 20 ms for converters 330 to attain rated reactive power transmission.

Referring to FIGS. 5 and 6 together, for case 2 described above, the total impedance of substation bus 352 coupling turbines 1 through 10 is relatively small as compared to the impedance of grid 333, and the voltage threshold determined to approximate the position of electrical faults within substation 350 is established at approximately 6%. Once converters 330 attain rated reactive power transmission within 20 ms, a determination is made within the next 20 ms if voltage has been restored to the predetermined value. In case 2, the voltage within substation 350 is not restored due to the low impedance. As shown in FIG. 6, each converter 330 associated each of turbines 1 through 10 indicates a substantially uniform 6% voltage increase. Therefore, since system 200 has determined that the fault is within substation 350, the LVRT/ZVRT features of system 200 to command converters 330 to support substation voltage are deactivated within 40 ms of initiation of the event, which is at least 10 ms earlier than the opening of the associated circuit breaker to isolate the fault, and all of turbines 1 through 10 are tripped to facilitate reducing the amount of electric current flowing to the fault prior to isolation. Such operation by system 200 decreases the amount of time that the arc associated with the electrical fault is energized.

Referring again solely to FIG. 5, in the exemplary embodiment, a third case is shown and described. Case 3 includes an electrical fault in the form of a short circuit upstream of transformer 338 associated with turbine 10. Voltage on the busses and components extending between transformer 338 and generator 318 (shown in FIG. 4) of turbine 10 decreases substantially instantaneously to approximately zero volts, thereby drawing down the voltage throughout wind turbine string 502. Protection and control system 200 receives voltage measurements from positions throughout wind turbine string 502 and substation 350 and system 200 includes sufficient programming to identify the occurrence of such fault. However, the location of such fault requires further determination by system 200.

As described above, in the exemplary embodiment, system 200 is programmed with sufficient data defining a voltage threshold curve that is a function of a value of the magnitude and/or percentage of the voltage increase, the time elapsed during the voltage increase, and the impedance of the electric cabling per unit distance. System 200 also includes sufficient programming to enable LVRT/ZVRT features therein to facilitate continued operation of a substantial portion of electric power generation facility 500 during such voltage transients induced by such wind turbine events. System 200 initially compensates for the voltage decrease on substation 350, wherein each converter controller 403 and/or park controller 404 commands an increase of reactive current output of associated converters 330 concurrently with electrical isolation activities of the site of the fault. Such isolation activities include operation of wind turbine isolation devices, e.g., automated opening of the nearest switch 326 and/or circuit breakers 334 and/or 342 to clear the fault. Typically, such isolation occurs after approximately three cycles, i.e., approximately 50 milliseconds (ms).

Such compensation includes the LVRT/ZVRT features of system 200 to command converters 330 of individual turbines 1 through 10 and electric power generation facility 500 to continue to transmit reactive current into substation bus 352 to facilitate stabilizing the substation voltage, thereby facilitating restoring and maintaining a substantially constant voltage on substation 350. Moreover, as the reactive power transmission from converters 330 increases, the active power component of the apparent power transmission value decreases, thereby facilitating a decrease of the magnitude of active current transmitted to the fault, and maintaining the apparent power output of converters 330 within predetermined parameters. Typically, it takes approximately 20 ms for converters 330 to attain rated reactive power transmission.

Referring to FIGS. 5 and 6 together, for case 3 described above, the total impedance of substation bus 352 and turbines 1 through 10 is relatively small as compared to the impedance of grid 333, and the voltage threshold determined to approximate the position of electrical faults within an affected wind turbine 300 is established at approximately 0%, while the unaffected wind turbines 300 have predetermined increased voltage values of approximately 12%. Once converters 330 attain rated reactive power transmission within 20 ms, a determination is made within the next 20 ms if voltage has been restored to the predetermined value. In case 3, the voltage within turbine 10 is not restored due to the fault thereon. As shown in FIG. 6, each converter 330 associated each of turbines 1 through 9 indicate a substantially uniform 12% voltage increase, while turbine 10 indicates a substantially 0% increase. Therefore, since system 200 has determined that the fault is within one of turbines 1 through 10, or more specifically, turbine 10, the LVRT/ZVRT features of system 200 to command converters 330 to support substation voltage are deactivated within 40 ms of initiation of the event, which is at least 10 ms earlier than the opening of the associated circuit breaker to isolate the fault, and all of turbines 1 through 10 are tripped to facilitate reducing the amount of electric current flowing to the fault prior to isolation. Such operation by system 200 decreases the amount of time that the arc associated with the electrical fault is energized.

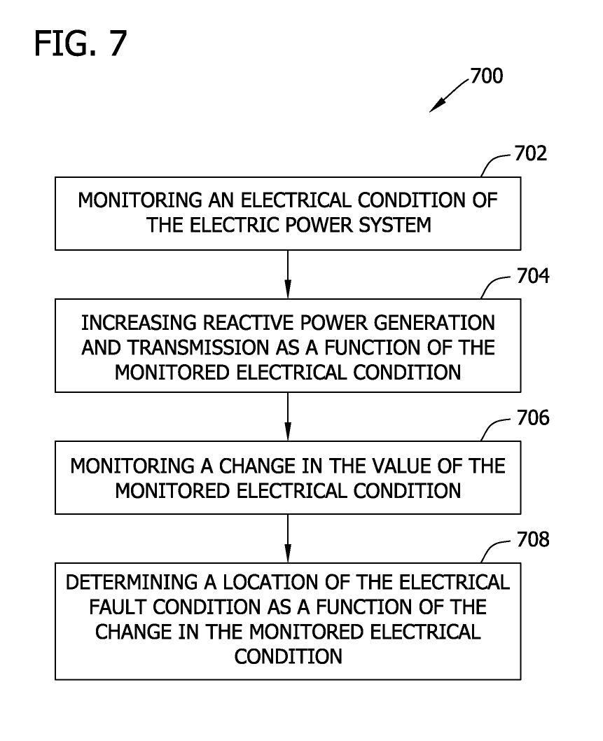

FIG. 7 is a flowchart of an exemplary method 700 of controlling electric power system 205 (shown in FIG. 5) during electrical fault conditions. In the exemplary embodiment, an electrical condition of electric power system 205 is monitored 702. Reactive power generation and transmission is increased 704 as a function of the monitored electrical condition. A change in the value of the monitored electrical condition is monitored 706. A location of the electrical fault condition as a function of the change in the monitored electrical condition is determined 708.

The above-described embodiments facilitate efficient and cost-effective operation of an electric power generation facility, such as a wind turbine farm and a collection of solar arrays. The electric power generation facility includes a protection and control system that facilitates identification of a location of an electrical fault on an electric power system. Specifically, the protection and control system facilitates identification of an electrical fault on the electric utility grid and/or within an electric power generation facility as a function of an increase in voltage generated by an electric power generation device. Also, the protection and control system facilitates deactivating LVRT and/or ZVRT features of an electric power generation device to decrease the effects of an electrical fault within the electric power generation facility. Further, the protection and control system facilitates providing additional reactive current output as a function of the location of the fault, thereby facilitating prevention of voltage collapse and improve the voltage stability of a deteriorated utility grid following a grid contingency event.

Exemplary embodiments of an electric power system, wind turbine, protection and control systems, and methods for operating an electric power system including a wind turbine in response to an occurrence of an electrical fault are described above in detail. The methods, wind turbine, and protection and control system are not limited to the specific embodiments described herein, but rather, components of the electric power system, wind turbine, components of the protection and control system, and/or steps of the methods may be utilized independently and separately from other components and/or steps described herein. For example, the protection and control system and methods may also be used in combination with other wind turbine power systems and methods, and are not limited to practice with only the power system as described herein. Rather, the exemplary embodiment can be implemented and utilized in connection with many other wind turbine or power system applications.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A protection and control system for an electric power system that includes at least one electric power generation device, said protection and control system comprising:
at least one voltage measurement device;
at least one memory device coupled to said voltage measurement device, said memory device configured to store a plurality of voltage measurements of the electric power system; and,
at least one processor coupled in communication with said memory device, said processor programmed to:
determine a change of voltage induced by an electric power generation device; and,
determine an approximate location of an electrical fault as a function of the change of voltage induced by the electric power generation device.

2. A system in accordance with claim 1, wherein said processor is further programmed to determine the location of the electrical fault as a function of an increase in voltage generated by the electric power generation device, wherein said increase in voltage is commanded by said processor.

3. A system in accordance with claim 1, wherein said processor is further programmed to determine the location of the electrical fault as a function of a plurality of impedance measurements of the electric power system, said memory device further configured to store the plurality of impedance measurements of the electric power system.

4. A system in accordance with claim 1, wherein said processor is further programmed to determine if the electrical fault is located within one of:
an electric utility grid portion of the electric power system; and,
an electric power generation facility of the electric power system.

5. A system in accordance with claim 4, wherein said processor is further programmed to determine the location of the electrical fault as a function of a difference between a measurement of the increased voltage and a predetermined threshold voltage value.

6. A system in accordance with claim 1, wherein said processor is further programmed to determine if:
a low voltage ride through (LVRT) feature for the electric power generation device is deactivated; and,
a zero voltage ride through (ZVRT) feature for the electric power generation device is deactivated.

7. A system in accordance with claim 1, wherein said processor is one of:
positioned within a plurality of controllers distributed within the electric power system, wherein each of said controllers is operatively coupled to at least one of at least one full power conversion assembly and at least one doubly-fed induction generator (DFIG) controller; and,
positioned within a centralized controller operatively coupled to at least one of at least one full power conversion assembly and at least one DFIG converter.

8. A method for controlling an electric power system during electrical fault conditions, the electric power system including at least one electric power generating device, and at least one controller, said method comprising:
monitoring an electrical condition of the electric power system;
increasing reactive power generation and transmission as a function of the monitored electrical condition;
monitoring a change in the value of the monitored electrical condition; and,
determining a location of the electrical fault condition as a function of the change in the monitored electrical condition.

9. A method in accordance with claim 8, wherein determining a location of the electrical fault condition comprises determining the location of the electrical fault condition on at least one of:
an electric utility grid portion of the electric power system; and,
an electric power generation facility of the electric power system.

10. A method in accordance with claim 9, wherein determining the location of the electrical fault condition on the electric utility grid portion of the electric power system comprises maintaining the electric power generating device in service, and, determining the location of the electrical fault condition on the electric power generation facility of the electric power system comprises removing the electric power generating device from service.

11. A method in accordance with claim 8, wherein monitoring an electrical condition of the electric power system comprises monitoring voltage values of an electric power generation facility.

12. A method in accordance with claim 8, wherein monitoring an electrical condition of the electric power system comprises monitoring an output voltage induced by a power converter.

13. A method in accordance with claim 8, further comprising controlling operation of the electric power generating device based at least partially on the change in the value of the monitored electrical condition.

14. A method in accordance with claim 13, wherein controlling operation of the electric power generating device based at least partially on the change in the value of the monitored electrical condition comprises one of:
maintaining activation of low voltage ride through (LVRT) and zero voltage ride through (ZVRT) operation of the electric power generating device; and,
deactivating low voltage ride through (LVRT) and zero voltage ride through (ZVRT) operation of the electric power generating device.

15. A method in accordance with claim 8, wherein determining a location of the electrical fault condition as a function of the change in the monitored electrical condition comprises determining a percentage increase in an output voltage induced by a power converter.

16. An electric power system comprising:
at least one electric power generating device;
at least one voltage measurement device;
at least one memory device coupled to said voltage measurement device, said memory device configured to store a plurality of voltage measurements of said electric power system; and,
at least one processor coupled in communication with said memory device, said processor programmed to:
determine a change of voltage induced by said electric power generation device; and,
determine an approximate location of an electrical fault as a function of the change of voltage induced by said electric power generation device.

17. A system in accordance with claim 16, wherein said processor is further programmed to determine the location of the electrical fault as a function of an increase in voltage generated by said electric power generation device, wherein said increase in voltage is commanded by said processor.

18. A system in accordance with claim 16, wherein said processor is further programmed to determine the location of the electrical fault as a function of a plurality of impedance measurements of said electric power system, said memory device further configured to store the plurality of impedance measurements of said electric power system.

19. A system in accordance with claim 16, wherein said processor is further programmed to determine if the electrical fault is located within one of:
an electric utility grid portion of said electric power system; and,
an electric power generation facility of said electric power system.

20. A system in accordance with claim 19, wherein said processor is further programmed to determine the location of the electrical fault as a function of a difference between a measurement of the increased voltage and a predetermined threshold voltage value.
